(19) United States
(12) Patent Application Publication
(10) Pub. No.: US 2011/0291136 A1
(43) Pub. Date: Dec. 1, 2011

(54) LIGHT-EMITTING ELEMENT AND FABRICATION METHOD THEREOF

(75) Inventors: TZU-CHIEN HUNG, Hukou Shiang (TW); CHIA-HUI SHEN, Hukou Shiang (TW)

(73) Assignee: ADVANCED OPTOELECTRONIC TECHNOLOGY, INC., Hsinchu Hsien 303 (TW)

(21) Appl. No.: 13/094,750

(22) Filed: Apr. 26, 2011

(30) Foreign Application Priority Data
May 28, 2010 (CN) 201010185791.1

(51) Int. Cl. H01L 33/58

(52) U.S. Cl. 257/98; 438/29; 257/E33.068

(57) ABSTRACT

A light-emitting element includes a substrate, a light-emitting module and at least two electrodes. The light-emitting module is formed on the substrate. The at least two electrodes are formed on the light-emitting module. Exterior surfaces of the light-emitting module are separated into a first part and a second part. The first part is defined between the at least two electrodes and the light-emitting module. The second part includes exterior surfaces not contacting the at least two electrodes. The first part is smooth. At least a part of the second part is rough.

### BACKGROUND

1. Technical Field

The disclosure relates in general to semiconductors, and more particular to a light-emitting element and fabrication method for the light-emitting element.

2. Description of the Related Art

Often, luminance of a light-emitting element is limited. Therefore, there is room for improvement in the art.

### BRIEF DESCRIPTION OF THE DRAWINGS

Many aspects of the embodiments can be better understood with references to the following drawings. The components in the drawings are not necessary drawn to scale, the emphasis instead being placed upon clear illustrating the principles of the embodiments. Moreover, in the drawings, like reference numerals designate corresponding parts throughout two views.

FIG. 1 is a flowchart of a fabrication method for a light-emitting element in accordance with the disclosure.

FIGS. 2-4 are schematic views of the fabrication method in FIG. 1.

FIG. 5 is a cross-section of a first embodiment of a light-emitting element in accordance with the disclosure.

FIG. 6 is a cross-section of a second embodiment of a light-emitting element in accordance with the disclosure.

FIG. 7 is a cross-section of a third embodiment of a light-emitting element in accordance with the disclosure.

### DETAILED DESCRIPTION

The disclosure is illustrated by way of example and not by way of limitation in the figures of the accompanying drawings. It should be noted that references to “an” or “one” embodiment in this disclosure are not necessari to the same embodiment, and such references mean at least one.

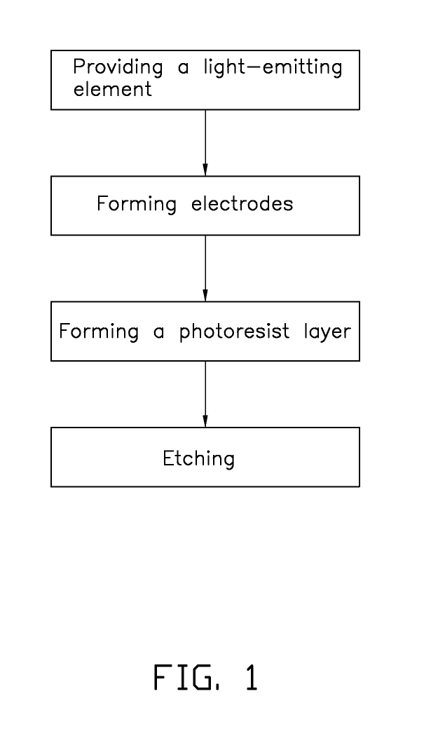

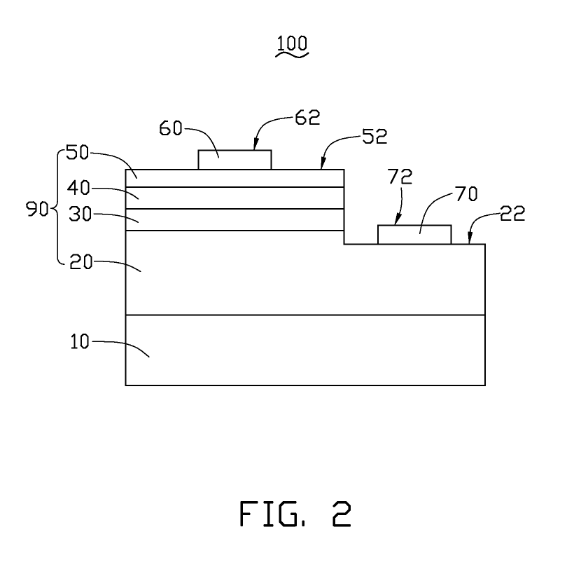

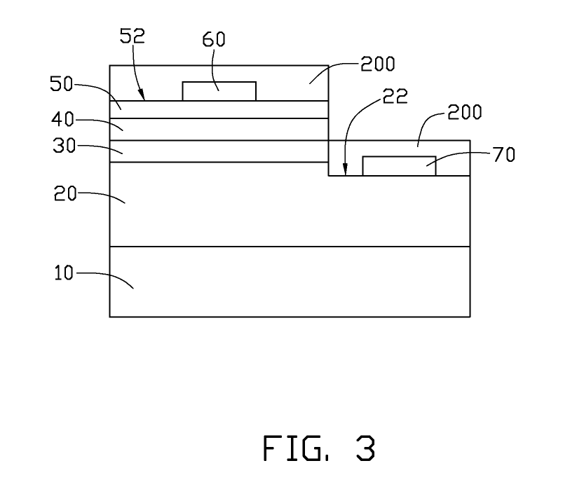

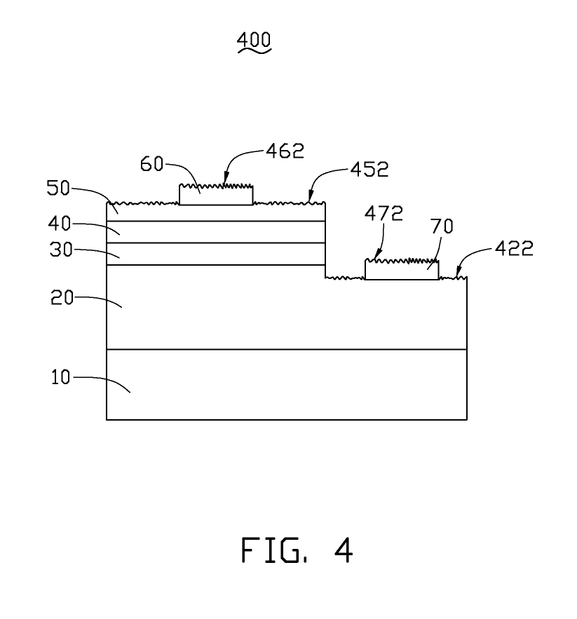

Referring to FIGS. 1-4, a fabrication method for a light-emitting element 100 in accordance with the disclosure is as follows.

A light-emitting element 100 is provided. The light-emitting element 100 includes a substrate 10 and a light-emitting module 90. In the first embodiment, the substrate 10 is sapphire. The light-emitting module 90 includes an N-type semi-conductive layer 20, a light-emitting layer 30, a P-type semi-conductive layer 40 and a diffusion layer 50. The N-type semi-conductive layer 20, the light-emitting layer 30 and the P-type semi-conductive layer 40 are AlₓIn_{y}Ga_{1-x-y}N, wherein 0≦x≦1, 0≦y≦1 and x+y≦1.

The N-type semi-conductive layer 20 is formed on the substrate 10 by metal organic chemical vapor deposition (MOCVD) or molecular beam epitaxy (MBE).

The light-emitting layer 30 is formed between the N-type semi-conductive layer 20 and the P-type semi-conductive layer 40.

The diffusion layer 50 is transparent and formed on the P-type semi-conductive layer 40. The diffusion layer 50 is configured for increasing current distribution to increase the luminance of the light-emitting element 100. The diffusion layer 50 is Ni—Au alloy, Indium Tin Oxide (ITO), Indium Zinc. Oxide (IZO), Indium Tungsten Oxide (IWO), Indium Gallium Oxide (IGO) or a combination thereof.

At least two electrodes are formed on the light-emitting module 90. In the first embodiment, a P-type electrode 60 is formed on the diffusion layer 50. An N-type electrode 70 is formed on the N-type semi-conductive layer 20. When the light-emitting element is fabricated as a vertical-type, the N-type electrode 70 and the P-type electrode 60 can be formed on the opposite side surfaces thereof. The N-type electrode 70 and the P-type electrode 60 are formed by vapor deposition or sputtering deposition.

A photoresist layer 200 is formed on exterior surfaces of the light-emitting module 90 and the P-type electrode 60 and the N-type electrode 70. The photoresist layer 200 is Propylene Glycol Mono-methyl Ether Acetate (PGMEA), Polymethylmethacrylate (PMMA) or a combination thereof. In the first embodiment, the photoresist layer 200 is formed on an exterior surface 52 of the current diffusion layer 50, an exterior surface 22 of the N-type semi-conductive layer 20, and exterior surfaces of the P-type electrode 60 and the N-type electrode 70. Optimally, thickness of the photoresist layer 200 is from 0.1 μm to 1 μm.

The photoresist layer 200 is etched, and rough surfaces of the light-emitting element 100 obtained. Light from the light-emitting module 90 can be emitted by several reflections between the rough surfaces. The photoresist layer 200 is etched by inductively coupled plasma etcher (ICP etcher). When the photoresist layer 200 is heated, non-regular patterns are formed between photoresist layer 200 and the exterior surfaces of the light-emitting element 100. Thus, roughness of the exterior surfaces of light-emitting element 100 is increased.

In the first embodiment, the photoresist layer 200 is formed on the exterior surface 52 of the diffusion layer 50 and the exterior surface 22 of the N-type semi-conductive layer 20, the exterior surfaces of the P-type electrode 60 and the N-type electrode 70. The rough surfaces 452, 462, 472 are respectively formed on the exterior surface 52 of the current diffusion layer 50 and the exterior surface 22 of the N-type semi-conductive layer 20, the exterior surfaces of the P-type electrode 60 and the N-type electrode 70.

When the photoresist layer 200 is etched, the rough surfaces of light-emitting element 100 are obtained. Light from the light-emitting element 100 can be reflected several times in the rough surfaces, increasing luminance of light-emitting element 100 considerably.

Because the surface between the P-type electrode 60 and the P-type semi-conductive layer 40 and the surface between the N-type electrode 70 and the N-type semi-conductive layer 20 are not rough, electrical characteristics, such as leakage current and operation voltage, are not changed.

Test data of 1000 light-emitting elements is shown in Table 1 and Table 2. The operation current of each light-emitting element is 350 mA.

TABLE 1
Light-emitting element without rough surface

| ITEM | Min. | Max. | Average |
|---|---|---|---|
| Voltage (V) | 3.0 | 4.0 | 3.92 |
| Luminance (mW) | 5.0 | 300.0 | 137.487 |
| Wavelength (nm) | 300.0 | 500.0 | 398.26 |

TABLE 2
Light-emitting element of rough surface

| ITEM | Min. | Max. | Average |
|---|---|---|---|
| Voltage (V) | 3.0 | 4.0 | 3.94 |
| Luminance (mW) | 5.0 | 300.0 | 164.551 |
| Wavelength (nm) | 300.0 | 500.0 | 398.84 |

Accordingly, luminance of the light-emitting element with rough surface increases effectively, electrical characteristics of the light-emitting element of rough surface, such as voltage and wavelength, are similar to those of the light-emitting element without rough surface, and mechanical structure of the light-emitting element is undamaged by forming the rough surface.

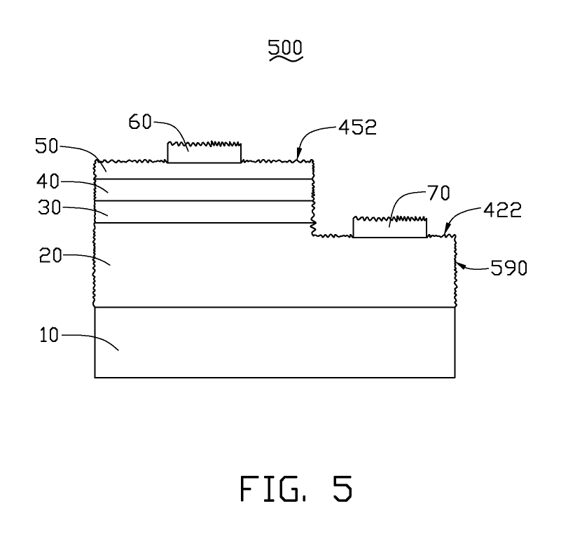

Referring to FIG. 5, a light-emitting element 500 in accordance with a second embodiment of the disclosure differs from light-emitting element 100 only in that the photoresist layer 200 is formed on all exterior surfaces of the light-emitting element 500, including upper surfaces and side surfaces of the light-emitting module 90, except the substrate 10.

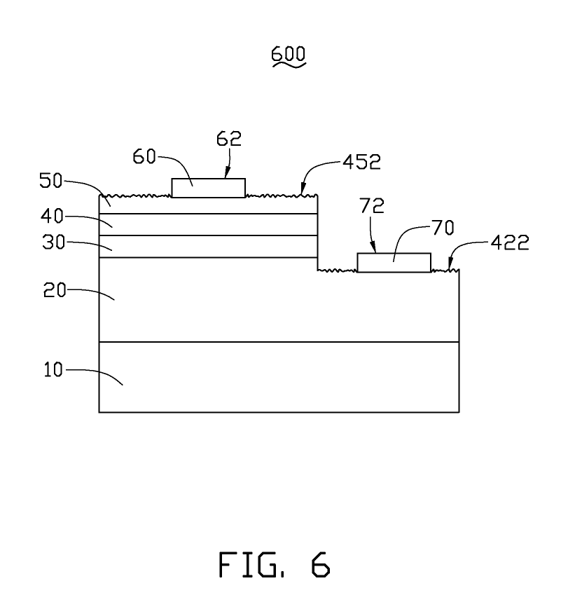

Referring to FIG. 6, a light-emitting element 600 in accordance with a third embodiment of the disclosure differs from light-emitting element 500 only in that protection layers are formed on the P-type electrode 60 and the N-type electrode 70 before the photoresist layer 200 is formed. According to the protection layers, upper surfaces 62, 72 of the P-type electrode 60 and the N-type electrode 70 are not rough when the photoresist layer 200 is etched. After the photoresist layer 200 is etched, the protection layers can be removed by chemical solutions. The protection layer is made of SiO₂, Si₃N₄ or a combination thereof.

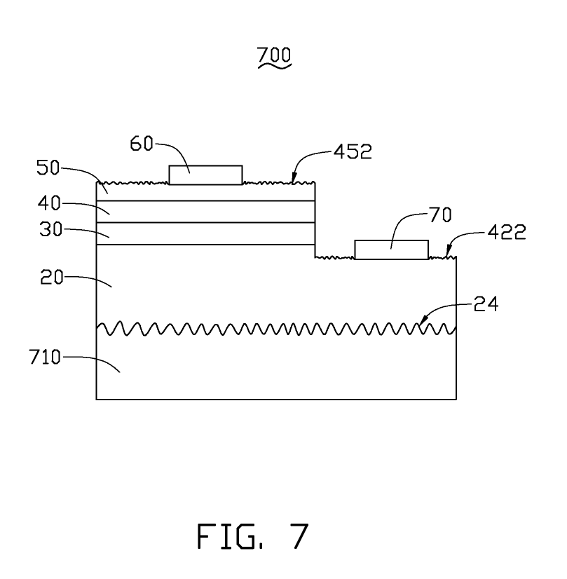

Referring to FIG. 7, a light-emitting element 700 in accordance with a fourth embodiment differs from light-emitting element 600 only in that a light diffusion surface 24 is formed between the N-type semiconductor layer 20 and the substrate 710. The light diffusion surface 24 is configured for diffusing light emitted to the substrate 710. Thus, the light from the light-emitting layer 30 can be utilized efficiently. The diffusion surface 24 is formed before forming the light emitting module on the substrate 710.

While the disclosure has been described by way of example and in terms of exemplary embodiment, it is to be understood that the disclosure is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light-emitting element comprising:
a substrate;
a light-emitting module formed on the substrate; and
at least two electrodes formed on the light-emitting module;
wherein exterior surfaces of the light-emitting module are separated into a first part and a second part, the first part defined between the at least two electrodes and the light-emitting module, the second part being exterior surfaces that do not contact the at least two electrodes, the first part being smooth, at least a part of the second part being rough.

2. The light-emitting element of claim 1, wherein all of the second part is rough.

3. The light-emitting element of claim 1, wherein exterior surfaces of the at least two electrodes are rough.

4. The light-emitting element of claim 1, wherein a light diffusion surface is defined between the substrate and the light-emitting module, the light diffusion surface being rough for diffusing light.

5. The light-emitting element of claim 1, wherein thickness of the at least a part of the second part is from 0.1 μm to 1 um.

6. A fabrication method for a light-emitting element, the method comprising:
providing a substrate and a light-emitting module;
forming electrodes on the light-emitting module;
forming a photoresist layer on an exterior surfaces of the light-emitting module; and
etching the photoresist layer to obtain a rough exterior surface.

7. The fabrication method for a light-emitting element package of claim 6, wherein the exterior surfaces includes side surfaces of the light-emitting module.

8. The fabrication method for a light-emitting element package of claim 6, further comprising:
forming protection layers on exterior surfaces of the electrodes before forming a photoresist layer on an exterior surfaces of the light-emitting module.

9. The fabrication method for a light-emitting element package of claim 6, further comprising:
etching a surface of the substrate,
wherein the light-emitting module is formed on the etched surface of the substrate.
